(19) United States
(12) Patent Application Publication
(10) Pub. No.: US 2005/0269715 A1
(43) Pub. Date: Dec. 8, 2005

(54) Semiconductor package, mold used in manufacturing the same, and method for manufacturing the same

(76) Inventor: Cheol-Joon Yoo, Cheonan-si (KR)

Correspondence Address: HARNESS, DICKEY & PIERCE, P.L.C., P.O. BOX 8910, RESTON, VA, 20195, US

(21) Appl. No.: 11/029,566

(22) Filed: Jan. 6, 2005

(30) Foreign Application Priority Data
Jun. 8, 2004 (KR) 2004-41855

(51) Int. Cl. H01L 23/48

(52) U.S. Cl. 257/780

(57) ABSTRACT

An apparatus, method and mold for manufacturing a semiconductor package are provided. The semiconductor package may include at least a semiconductor chip positioned on a substrate, a bonding wire for electrically connecting the semiconductor chip to the substrate, an encapsulant for enclosing the semiconductor chip and sides of the substrate, and a conductor connector attached to a lower surface of the substrate.

This U.S. non-provisional application claims priority to Korean Patent Application No. 2004-41855, filed on Jun. 8, 2004, in the Korean Intellectual Property Office, the contents of which are incorporated by reference herein in their entirety.

### BACKGROUND OF THE INVENTION

1. Field of the Invention

Exemplary embodiments of the present invention may generally relate to a semiconductor package, a mold for use in manufacturing the same, and a method for manufacturing the semiconductor package.

2. Description of the Related Art

Electronic products of today are evolving toward designing light weight, high speed, multi-function, and/or high reliable products. One manner of making it possible to achieve such product design may be in a semiconductor package technology, which may employ a BOC (board on chip) semiconductor package process.

FIG. 1 is a cross-sectional view of a conventional BOC semiconductor package, and FIG. 2 is a partial, enlarged view of the conventional BOC semiconductor package of FIG. 1.

The conventional BOC semiconductor package may use a PCB (printed circuit board) 103 having a window (opening) 101 on its center. A semiconductor chip 105 may be attached, with its face down, on the PCB substrate 103, and a pad (not shown) formed on a center of the semiconductor chip. Further, the semiconductor chip 105 may be connected to the PCB substrate 103 with use of bonding wires 107 passing through the window 101. Also, the window 101 formed on the PCB substrate 103 may be buried (e.g., enclosed), and an upper part of the PCB substrate 103 and the semiconductor chip 105 may be sealed by an encapsulant 109 such as, for example an EMC (epoxy molding compound). A solder ball 111 may be formed on a lower surface of the PCB substrate 103. An adhesive 113 may be used to attach the semiconductor chip 105 to the PCB substrate 103, as shown in FIG. 2.

Because the conventional BOC semiconductor package may have a structure where sides of the PCB substrate 103 may be exposed, a separation distance “a” between an edge of the semiconductor chip 105 and an appearance (e.g., edge of the semiconductor package), may not be sufficiently secured. Accordingly, in the conventional BOC semiconductor package, since an adhesive surface between the encapsulant 109 and the PCB substrate 103 may not be sufficiently secured, detachment may occur where the encapsulant 109 and the PCB substrate 103 are located, as shown by reference numeral 115 in FIG. 2.

Also, in the conventional BOC semiconductor package, since the separation distance “a” between the edge of the semiconductor chip 105 and the appearance may not be sufficiently secured, a path for absorbing humidity may be formed, which may penetrate into the semiconductor chip 105 and produce a short circuit. As a result, the reliability of the package may be reduced.

### SUMMARY OF THE INVENTION

Exemplary embodiments of the present invention may provide a semiconductor package having at least a semiconductor chip positioned on a substrate, a bonding wire for electrically connecting the semiconductor chip to the substrate, an encapsulant for enclosing the semiconductor chip and sides of the substrate, and a solder ball attached to a lower surface of the substrate.

In other exemplary embodiments, the encapsulant may be formed at an edge in a lower surface of the substrate to enclose the sides of the substrate.

In other exemplary embodiments, the substrate may be a printed circuit board (PCB).

Exemplary embodiments of the present invention may provide a semiconductor package having a printed circuit board (PCB) substrate having a window, a semiconductor chip mounted on the PCB substrate, a bonding wire for electrically connecting the semiconductor chip to the PCB substrate, the bonding wire passing through the window, an encapsulant for enclosing the semiconductor chip and sides of the PCB substrate, and a conductive connector attached to a lower surface of the PCB substrate.

In other exemplary embodiments, the window may be in a center of the PCB substrate.

In other exemplary embodiments, the semiconductor chip may be mounted with an active surface down on the PCB substrate.

In other exemplary embodiments, the encapsulant may be buried in the window of the PCB substrate where the bonding wire is formed.

In yet other exemplary embodiments, the encapsulant buried in the window of the PCB substrate may be formed higher than the lower surface of the PCB substrate.

In other exemplary embodiments, the encapsulant may be formed at an edge of the lower surface of the PCB substrate to enclose the sides of the PCB substrate.

In other exemplary embodiments, the encapsulant may be an epoxy molding compound.

In other exemplary embodiments, ends of the semiconductor chip and PCB substrate may be formed along the same edge.

In other exemplary embodiments, an adhesive between the semiconductor chip and the PCB substrate may be provided.

Exemplary embodiments of the present invention may provide a mold for use in manufacturing having a lower mold where a substrate having a plurality of semiconductor chips and a stick-type through gate on partition parts for partitioning the substrate into a separate semiconductor package, may be mounted, the lower mold having a lower cavity that corresponds to where the stick-type through gate of the substrate may be formed, and an upper mold positioned on the lower mold where the substrate having the stick-type through gate may be mounted, the upper mold having an upper cavity into which an encapsulant may be injected.

In other exemplary embodiments, a window may be formed at a center of each substrate constituting a matrix substrate so that a cavity may be formed at a part of the lower mold that corresponds to the window.

In other exemplary embodiments, the through gate may be formed at four partition parts for partitioning the substrate into a separate semiconductor package.

In yet other exemplary embodiments, the through gate may be formed at either of the four partition parts for partitioning the substrate into a separate semiconductor package.

In yet other exemplary embodiments, the through gate may be formed at two partition parts for partitioning the substrate into a separate semiconductor package.

In yet other exemplary embodiments, the two partition parts may be in a vertical direction.

In other exemplary embodiments, the through gate may be a stick-type.

In other exemplary embodiments, the lower cavity in the lower mold corresponds to where the stick-type through gate is formed.

In other exemplary embodiments, a groove may be formed on a surface of the encapsulant at the partition part of the substrate so as to ease the cutting by reducing a height of the encapsulant.

In other exemplary embodiments, the substrate may be a printed circuit board matrix.

Exemplary embodiments of the present invention may provide a mold for use in manufacturing having at least a lower mold having a lower cavity, and an upper mold having an upper cavity into which an encapsulant may be injected, wherein a substrate having a plurality of semiconductor chips and a through gate, may be mounted on the lower mold, and the lower cavity may be formed on the lower mold that corresponds to where the through gate is formed.

Exemplary embodiments of the present invention may provide a method for manufacturing including at least mounting a plurality of semiconductor chips on a substrate where a through gate may be formed on a partition part for partitioning the substrate into a separate semiconductor package, electrically connecting the semiconductor chip to the substrate using a bonding wire, mounting the substrate on which the semiconductor chip may be mounted, between a lower mold having a lower cavity and an upper mold having an upper cavity, enclosing and sealing the semiconductor chip and sides of the substrate by injecting an encapsulant into the lower and the upper cavities, attaching a conductive connector on a lower surface of the substrate, and completing a separate semiconductor package by cutting off the encapsulant formed at the partition part of the substrate.

Exemplary embodiments of the present invention may provide a method for manufacturing including at least mounting a plurality of semiconductor chips on a substrate where a through gate may be formed on a partition part for partitioning the substrate into a separate semiconductor package, electrically connecting the semiconductor chip to the substrate using a bonding wire, mounting the substrate on which the semiconductor chip may be mounted, between a lower mold having a lower cavity and an upper mold having an upper cavity, and enclosing and sealing the semiconductor chip and sides of the substrate by injecting an encapsulant into the lower and the upper cavities.

Exemplary embodiments of the present invention may provide a semiconductor package capable of reducing and/or preventing detachment of the encapsulant from the PCB substrate, and reducing and/or preventing humidity from entering the humidity absorption path.

Exemplary embodiments of the present invention may provide a mold for use in manufacturing the semiconductor package.

Exemplary embodiments of the present invention may also provide a method for manufacturing a semiconductor package, which may be capable of reducing and/or preventing detachment of the encapsulant from the PCB substrate, and blocking off the humidity absorption path through which humidity may penetrate into the semiconductor chip.

### BRIEF DESCRIPTION OF THE DRAWINGS

The present invention will become more apparent by describing in detail exemplary embodiments thereof with reference to the attached drawings in which:

FIG. 1 is a cross-sectional view of a conventional BOC semiconductor package;

FIG. 2 is a partial, enlarged view of the conventional BOC semiconductor package of FIG. 1;

FIG. 3 is a cross-sectional view of a BOC semiconductor package according to an exemplary embodiment of the present invention;

FIG. 4 is a partial, enlarged view of the BOC semiconductor package of FIG. 3;

FIG. 5 is a cross-sectional view of a semiconductor package according to another exemplary embodiment of the present invention;

FIG. 6 is a partial, enlarged view of the semiconductor package of FIG. 5;

FIGS. 7 and 8 are plan views showing a lower side of the PCB matrix substrate according to exemplary embodiments of the present invention;

FIG. 9 is an enlarged view showing a lower side of a PCB substrate of FIG. 7 according to an exemplary embodiment of the present invention;

FIGS. 10 and 11 are views showing a mold of exemplary embodiments of the present invention;

FIG. 12 is a flowchart illustrating a method for manufacturing a semiconductor package according to an exemplary embodiment of the present invention; and

FIGS. 13 and 14 are cross-sectional views illustrating a process for cutting off a semiconductor package according to an exemplary embodiment of the present invention.

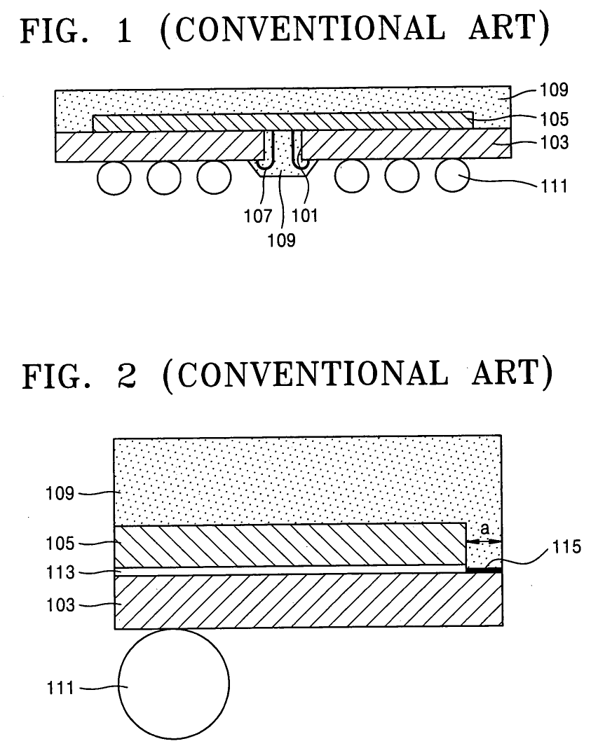

### DETAILED DESCRIPTION OF EXEMPLARY EMBODIMENTS

Exemplary embodiments of the present invention will now be described more fully with reference to the accompanying drawings. The invention may, however, be embodied in many different forms and should not be construed as being limited to the exemplary embodiments set forth herein. Rather, the exemplary embodiments are provided so that this disclosure will be thorough and complete, and will fully convey the concept of the invention to those skilled in the art.

It should be noted that the figures are intended to illustrate the general characteristics of methods and devices of exemplary embodiments of this invention, for the purpose of the description of such exemplary embodiments herein. These drawings are not, however, to scale and may not precisely reflect the characteristics of any given embodiment, and should not be interpreted as defining or limiting the range of values or properties of exemplary embodiments within the scope of this invention. Rather, for simplicity and clarity of illustration, the dimensions of some of the elements are exaggerated relative to other elements.

In particular, the relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer. Further, it will be understood that when a layer is referred to as being “on” or “formed over” another layer or substrate, the layer may be directly on the other layer or substrate, or intervening layer(s) may also be present.

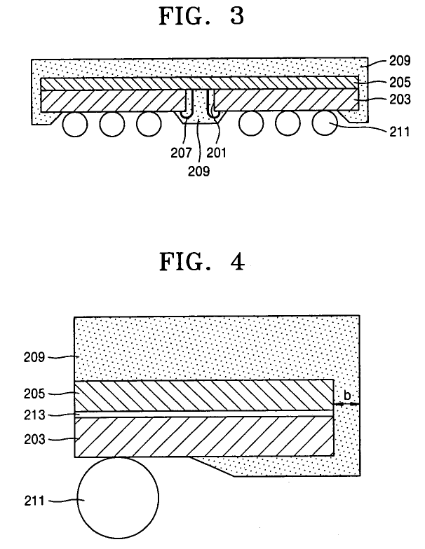

FIG. 3 is a cross-sectional view of a BOC semiconductor package according to an exemplary embodiment of the present invention, and FIG. 4 is a partial, enlarged view of the BOC semiconductor package of FIG. 3.

The BOC semiconductor package according to an exemplary embodiment of the present invention may use a PCB substrate 203 having a window (opening 201) . As an exemplary embodiment, the window 201 may be at a center of the substrate 203. A semiconductor chip 205 may be attached, with its surface down, on the PCB substrate 203 and a pad (not shown) formed on the semiconductor chip 205. It should be understood that the pad may be formed on a center and/or other regions of the semiconductor chip. The semiconductor chip 205 may be connected to the PCB substrate 203 with use of a bonding wire 207 passing through a window 201.

The window 201 formed on the PCB substrate 203 may be buried, and the semiconductor chip 205 including sides of the PCB substrate 203 may be enclosed and sealed with an encapsulant 209 such as, for example, an epoxy molding compound (EMC). It should be appreciated that other compounds may be used to enclose and seal the semiconductor chip. The encapsulant 209 may be formed by being buried in the window 201 of the PCB substrate 203 (e.g., formed higher than a lower part of the PCB substrate 203). The encapsulant 209 may also be formed at the edge in the lower surface of the PCB substrate 203 SO that the encapsulant 209 may approximately enclose the PCB substrate 203. A conductive connector, such as solder balls 211 may be formed on a lower surface of the PCB substrate 203. It should be appreciated that other conductive connectors may be employed. An adhesive 213 may be used to attach the semiconductor chip 205 to the PCB substrate 203, as shown in FIG. 2. It should be appreciated that other attachments may be used to attach the semiconductor chip to the PCB substrate.

Because the BOC semiconductor package according to an exemplary embodiment of the present invention may have a structure where the sides of the PCB substrate 203 are not exposed, the separation distance “b” between an edge of the semiconductor chip 205 and an appearance (e.g., edge of the semiconductor package), may be sufficiently secured. In other words, because the separation distance “b” of the BOC semiconductor package may be smaller than the separation distance “a” of the conventional art, it may be possible to increase the semiconductor chip size. As a result, the size of the semiconductor chip may be accommodated to the same maximum package size.

Further, because the BOC semiconductor package may have a structure where the sides of the PCB substrate 203 are not exposed, it may be possible to reduce and/or prevent detachment where the encapsulant 209 and the PCB substrate 203 are separated, and to block off the humidity absorption path through which humidity may penetrate into the semiconductor chip.

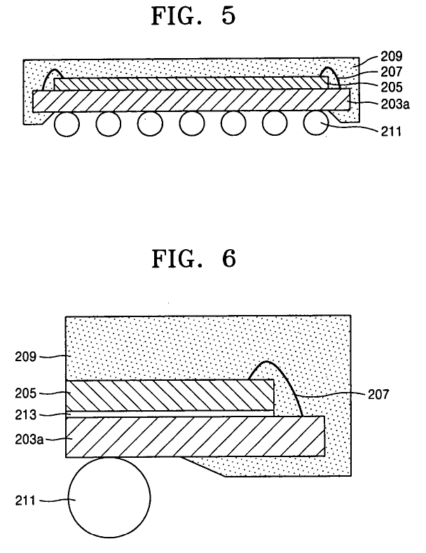

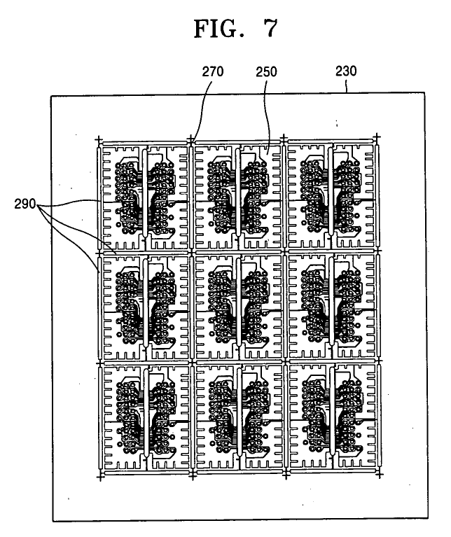

FIG. 5 is a cross-sectional view of the semiconductor package according to another exemplary embodiment of the present invention, and FIG. 6 is a partial, enlarged view of the semiconductor package of FIG. 5.

FIGS. 5 and 6 illustrate a semiconductor package that may be a general package, rather than a BOC structure, as shown in FIGS. 3 and 4. The same reference numerals as those in FIGS. 5 and 6 represent the same members as those in FIGS. 3 and 4.

The semiconductor package according to an exemplary embodiment of the present invention may use a general PCB substrate 203a. A semiconductor chip 205 may be attached on the PCB substrate 203a and a pad (not shown) formed at an edge of the semiconductor chip 205. It should be understood that the pad may be formed at other regions of the semiconductor chip. The semiconductor chip 205 may be connected to the PCB substrate 203a by, for example, but not limited to bonding wires 207.

The semiconductor chip 205 and sides of the PCB substrate 203a may be enclosed and sealed with an encapsulant 209 such as, for example, an epoxy molding compound (EMC). It should be appreciated that other compounds may be used to enclose and seal the semiconductor chip. The encapsulant 209 may also be formed at the edge of a lower surface of the PCB substrate 203a, so as to approximately enclose the PCB substrate 203a. A solder ball 211 may be formed on a lower surface of the PCB substrate 203a. An adhesive 213 may be used to attach the semiconductor chip 205 to the PCB substrate 203a, as shown in FIG. 6. It should be appreciated that other attachments may be used to attach the semiconductor chip to the PCB substrate.

Because the semiconductor package according to an exemplary embodiment of the present invention may have a structure such that the sides of the PCB substrate 203a may not be exposed, it may be possible to reduce and/or prevent detachment of the encapsulant 209 and the PCB substrate 203a, and block off the humidity absorption path through which humidity may penetrate into the semiconductor chip 205.

A method for manufacturing the BOC semiconductor package according to an exemplary embodiment of the present invention will now be described. Generally, the semiconductor package may be completed into a separate package by performing a molding and a cutting process after a plurality of semiconductor chips are mounted on the PCB matrix substrate.

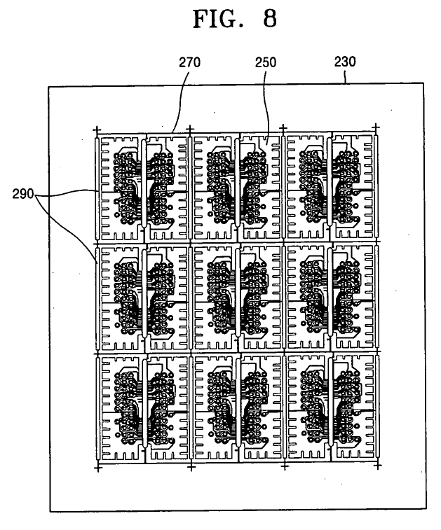

FIGS. 7 and 8 are plan views illustrating a backside of the PCB matrix substrate according to exemplary embodiments of the present invention.

The PCB matrix substrate 230 shown in FIGS. 7 and 8 may be divided into a plurality of semiconductor mounting parts 250 on which semiconductor chips may be mounted and a partition part 270 located between the semiconductor mounting parts 250. The partition part 270 may be formed for partitioning the PCB matrix substrate 230 into separate semiconductor packages. Further, the partition part 270 may be prepared so as to be cut off at the final process when completing a separate semiconductor package.

Also, the PCB matrix substrate 230 shown in FIGS. 7 and 8 may have, for example a stick-type through gate 290 at the partition part 270. As shown in FIG. 7, the stick-type through gate 290 may be formed at all four partition parts 270 for partitioning one separate semiconductor package. As shown in FIG. 8, the stick-type through gate 290 may be formed only at two parts (e.g., vertical direction) among the four partition parts 270 for partitioning one separate semiconductor 290. It should further be appreciated that the stick-type through gate 290 may be formed at any part or only three parts among the four partition parts 270 for partitioning one separate semiconductor 290.

If the PCB matrix substrate 230 is mounted on a molding apparatus during a molding process for manufacturing the semiconductor package, the encapsulant may be injected through the stick-type through gate 290 so that the semiconductor chip and the sides of the PCB substrate 230 may be enclosed by the encapsulant 209.

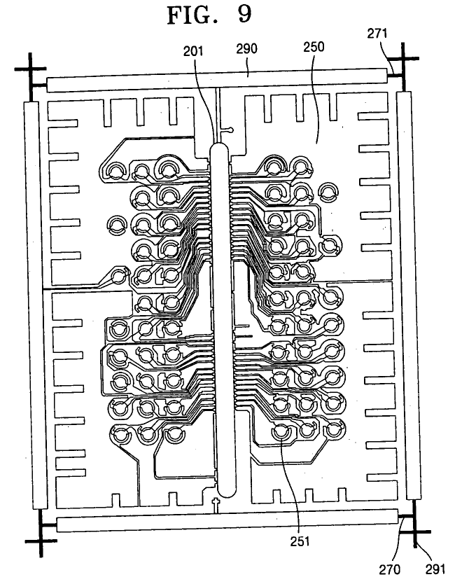

FIG. 9 is an enlarged view illustrating a lower side of one PCB substrate 230 of FIG. 7. More specifically, a semiconductor chip (refer to reference numeral 205 in FIG. 3) may be mounted, with its surface down, on an upper side (not shown) of the PCB substrate 230. A pad (not shown) formed on a center of the semiconductor chip may correspond to a window 201 formed on a center of the PCB substrate 230 upon mounting of the semiconductor chip.

As described above, the PCB substrate 230 may be divided into a semiconductor mounting part 250 on which a semiconductor chip may be mounted and a partition part 270 located between the semiconductor mounting parts. The partition part 270 may be formed for partitioning the PCB matrix substrate 230 into separate semiconductor packages. A ball land area 251 may be located at the semiconductor chip mounting part 250 and between the stick-type through gate 290. The ball land area 251 may be formed where the solder balls are formed. Further, an align mark 291 may be formed at the partition part 270.

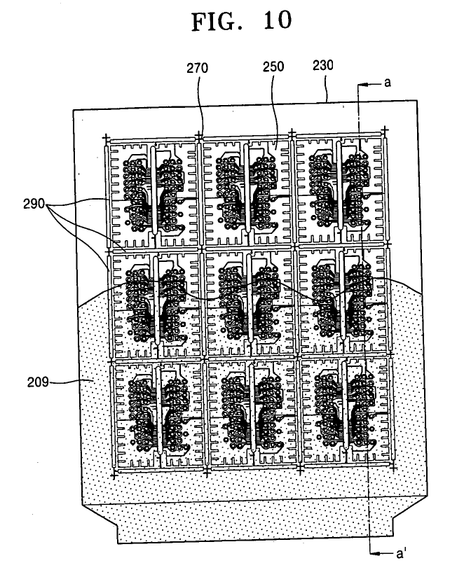

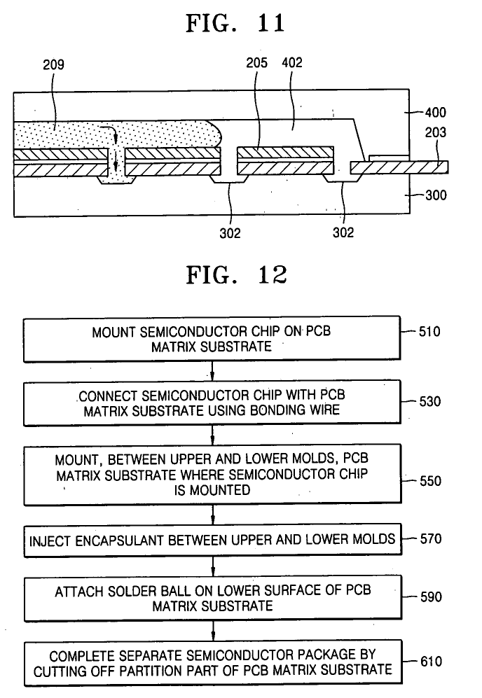

FIGS. 10 and 11 are views illustrating an exemplary embodiment of a mold of the present invention. FIG. 10 illustrates the encapsulant filled along line a-a', and FIG. 11 is a cross-sectional view taken along line a-a' of FIG. 10 with the PCB matrix substrate of FIG. 10 mounted.

The mold according to an exemplary embodiment of the present invention may include at least a lower mold 300 and an upper mold 400. A PCB matrix substrate 230 shown in FIG. 10 may be mounted on the lower mold 300. A plurality of semiconductor chips may be mounted on the PCB matrix substrate 230, and a stick-type through gate 290 may be formed at the partition part for partitioning a separate semiconductor package. As described above, the stick-type through gate 290 may be formed at all the four partition parts for partitioning the PCB matrix substrate 230 into a separate semiconductor package or only at either of the four partition parts. As an exemplary embodiment, FIG. 10 illustrates that the stick-type through gate 290 may be formed at all four partition parts as similarly shown in FIG. 7.

A lower cavity 302 of the lower mold 300, into which an encapsulant may be injected, may be formed at a part that corresponds to the stick-type through gate 290 of the PCB matrix substrate 230. In an exemplary embodiment that discloses a window (refer to reference numeral 201 of FIG. 9), the window may be formed at the center of each PCB substrate constituting the PCB matrix substrate 230. The lower cavity 302 may then be formed at the part of the lower mold 300 that may correspond to the window.

The upper mold 400 may be positioned on the lower mold 300 on which the PCB matrix substrate 230 having the stick-type through gate 290, may be mounted. An upper cavity 402 into which an encapsulant 209 may be injected, may be formed at the upper mold 400. As an exemplary embodiment, the encapsulant 209 may be injected in a left to right direction as shown in FIG. 11, filling the lower cavity 302 and the upper cavity 402.

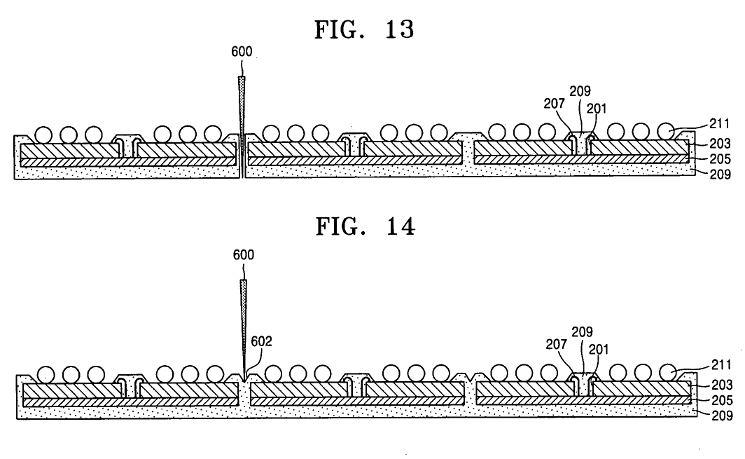

FIG. 12 is a flowchart illustrating a method for manufacturing a semiconductor package according to an exemplary embodiment of the present invention, and FIGS. 13 and 14 are cross-sectional views illustrating a process for cutting off a semiconductor package according to an exemplary embodiment of the present invention.

Referring to FIG. 12, a PCB matrix substrate may be prepared where a stick-type through gate may be formed at a partition part by partitioning the PCB matrix substrate into separate semiconductor packages. Accordingly, a plurality of semiconductor chips may be mounted on a semiconductor chip mounting part of the PCB matrix substrate (operation 510).

The semiconductor chip may be electrically connected to the PCB matrix substrate by, for example, a bonding wire (operation 530). When the semiconductor chip is connected to the PCB matrix substrate by the bonding wire, then a connection may be made through the window formed at the center of the PCB substrate (as shown in the case of the BOC structure of FIG. 3), or connection may be directly made (as shown in the case of FIG. 5).

Referring to FIGS. 10 and 11, a molding process may be performed for the semiconductor chip mounted on the PCB matrix substrate. Accordingly, the molding process may be performed by mounting the PCB matrix substrate on which the semiconductor chip is mounted (operation 550) (e.g., between the lower mold where a lower cavity is formed at its part that may correspond to the stick-type through gate of the PCB matrix substrate, and the upper mold having an upper cavity). Subsequently, the encapsulant 209 may be injected into the lower and the upper cavities so that the semiconductor chip and the sides of the PCB matrix substrate may be enclosed and sealed (operation 570).

A solder ball may be attached to a lower surface of the PCB matrix substrate. The solder ball may be attached to the ball land area 251 as shown in FIG. 9 (operation 590).

Referring to FIGS. 13 and 14, the encapsulant 209 formed at the partition part of the PCB matrix substrate may be cut off as shown by the reference numeral 600, so that a separate semiconductor package formed on the PCB substrate may be completed.

Because the encapsulant 209 may be cut off when the PCB matrix substrate is cut, the sides of the PCB substrate where the semiconductor chip is mounted, may be sealed by the encapsulant so that the completed separate semiconductor package may not be exposed. As shown in FIG. 14, a groove 602 may be provided for reducing a height of the encapsulant by easily making the cutting stage of the encapsulant at the partition part of the PCB matrix substrate (operation 610).

Exemplary embodiments of the present invention may have a structure such that the sides of the PCB substrate may not be exposed. Therefore, exemplary embodiments of the present invention may increase the size of the semiconductor chip to a maximum size so as possibly accommodate the same package size.

Further, exemplary embodiments of the present invention may not need to expose the sides of the PCB substrate so that detachment between that the encapsulant and the PCB substrate may be reduced and/or prevented, and so that the humidity absorption path may be blocked off through which humidity may penetrate into the semiconductor chip.

Further, exemplary embodiments of the present invention may provide mounting the PCB matrix substrate between the upper and the lower molds so that the encapsulant may be cut off and the sides of the PCB substrate may not be exposed.

It should be understood by one skilled in the art that “encapsulant” may generally relate to other compounds, such as but not limited to, epoxy resins, polyurethane resins, epoxy adhesives and/or other types of adhesive bonding materials.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor package, comprising:
a semiconductor chip positioned on a substrate;
a bonding wire for electrically connecting the semiconductor chip to the substrate;
an encapsulant for enclosing the semiconductor chip and sides of the substrate; and
a solder ball attached to a lower surface of the substrate.

2. The semiconductor package of claim 1, wherein the encapsulant is formed at an edge of a lower surface of the substrate to enclose the sides of the substrate.

3. The semiconductor package of claim 1, wherein the substrate is a printed circuit board (PCB).

4. A semiconductor package, comprising:
a printed circuit board (PCB) substrate having a window;
a semiconductor chip mounted on the PCB substrate;
a bonding wire for electrically connecting the semiconductor chip to the PCB substrate, the bonding wire passing through the window;
an encapsulant for enclosing the semiconductor chip and sides of the PCB substrate; and
a conductive connector attached to a lower surface of the PCB substrate.

5. The semiconductor package of claim 4, wherein the encapsulant is formed at an edge of the lower surface of the PCB substrate to enclose the sides of the PCB substrate.

6. The semiconductor package of claim 4, wherein the window is in a center of the PCB substrate.

7. The semiconductor package of claim 4, wherein the semiconductor chip is mounted with an active surface down on the PCB substrate.

8. The semiconductor package of claim 4, wherein the encapsulant is buried in the window of the PCB substrate where the bonding wire is formed.

9. The semiconductor package of claim 8, wherein the encapsulant buried in the window of the PCB substrate is formed higher than the lower surface of the PCB substrate.

10. The semiconductor package of claim 4, wherein the encapsulant is an epoxy molding compound.

11. The semiconductor package of claim 4, wherein ends of the semiconductor chip and PCB substrate are formed along the same edge.

12. The semiconductor package of claim 4, further comprises an adhesive between the semiconductor chip and the PCB substrate.

13. A mold for use in manufacturing, comprising:
a lower mold where a substrate having a plurality of semiconductor chips and a through gate on partition parts for partitioning the substrate into a separate semiconductor package, is mounted, the lower mold having a lower cavity that corresponds to where the through gate of the substrate is formed; and
an upper mold positioned on the lower mold where the substrate having the through gate is mounted, the upper mold having an upper cavity into which an encapsulant can be injected.

14. The mold of claim 13, wherein a window is formed at a center of each substrate constituting a matrix substrate so that a cavity is formed at a part of the lower mold that corresponds to the window.

15. The mold of claim 13, wherein the through gate is formed at four partition parts for partitioning the substrate into a separate semiconductor package.

16. The mold of claim 15, wherein the through gate is formed at either of the four partition parts for partitioning the substrate into a separate semiconductor package.

17. The mold of claim 13, wherein the through gate is formed at two partition parts for partitioning the substrate into a separate semiconductor package.

18. The mold of claim 17, wherein the two partition parts are in a vertical direction.

19. The mold of claim 13, wherein the substrate is a printed circuit board matrix.

20. The mold of claim 13, wherein the through gate is a stick-type.

21. A mold for use in manufacturing, comprising:
a lower mold having a lower cavity; and
an upper mold having an upper cavity into which an encapsulant is injected,
wherein a substrate having a plurality of semiconductor chips and a through gate, is mounted on the lower mold, and
the lower cavity is formed on the lower mold that corresponds to where the through gate is formed.

22. A method for manufacturing, comprising:
mounting a plurality of semiconductor chips on a substrate where a through gate is formed on a partition part for partitioning the substrate into a separate semiconductor package;
electrically connecting the semiconductor chip to the substrate using a bonding wire;
mounting the substrate on which the semiconductor chip is mounted, between a lower mold having a lower cavity and an upper mold having an upper cavity;
enclosing and sealing the semiconductor chip and sides of the substrate by injecting an encapsulant into the lower and the upper cavities;
attaching a conductive connector on a lower surface of the substrate; and
completing a separate semiconductor package by cutting off the encapsulant formed at the partition part of the substrate.

23. A method for manufacturing, comprising:
mounting a plurality of semiconductor chips on a substrate where a through gate is formed on a partition part for partitioning the substrate into a separate semiconductor package;
electrically connecting the semiconductor chip to the substrate using a bonding wire;
mounting the substrate on which the semiconductor chip is mounted, between a lower mold having a lower cavity and an upper mold having an upper cavity; and
enclosing and sealing the semiconductor chip and sides of the substrate by injecting an encapsulant into the lower and the upper cavities.
